(19) United States
(12) Patent Application Publication
(10) Pub. No.: US 2009/0095989 A1
(43) Pub. Date: Apr. 16, 2009

(54) MULTI-FINGER TRANSISTORS INCLUDING PARTIALLY ENCLOSING CONDUCTIVE LINES

(75) Inventor: Han-Su Kim, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/247,783

(22) Filed: Oct. 8, 2008

(30) Foreign Application Priority Data
Oct. 10, 2007 (KR) 10-2007-0102101

(51) Int. Cl. H01L 29/812

(52) U.S. Cl. 257/259; 257/E29.319

(57) ABSTRACT

A multi-finger transistor includes gate fingers disposed on a substrate, at least one gate wiring connected to end portions of the gate fingers, source regions and drain regions disposed between the gate fingers, a conductive line partially enclosing the gate fingers and the gate wiring, and substrate plugs electrically connecting the conductive line to the substrate. The conductive line is separated from the gate fingers and the gate wiring. Since the conductive line and the substrate plugs may partially, but not fully, enclose a portion of the substrate where the gate fingers and the gate wiring are positioned, parasitic capacitances caused by the conductive line and the substrate plugs may be considerably reduced to thereby allow high RF frequency characteristics of the multi-finger transistor.

### CROSS REFERENCE TO RELATED APPLICATION

This application claims priority under 35 USC §119 to Korean Patent Application No. 10-2007-0102101, filed on Oct. 10, 2007, the disclosure of which is hereby incorporated herein by reference in its entirety as if set forth fully herein.

### BACKGROUND

Example embodiments relate to semiconductor devices and methods of manufacturing the same. More particularly, example embodiments relate to a multi-finger transistors, and methods of manufacturing the multi-finger transistors.

High frequency transistors are widely used in radio frequency (RF) communications such as wireless local area networks (LAN) or Bluetooth communications. The high frequency transistor may correspond to a metal semiconductor field effect transistor (MESFET) including a semiconductor material in Group III or Group V, a bipolar transistor, a complementary metal oxide semiconductor (CMOS) transistor, etc. The CMOS transistor may be fabricated with a relatively low cost and also may have good cut-off frequency (Ft) and good maximum oscillation (Fmax) characteristics, so that the CMOS transistor may be employed in an RF circuit having a relatively low frequency. However, a multi-finger transistor may also be used as the high frequency transistor because the multi-finger transistor may have high current driving characteristics and good high frequency RF characteristics.

The multi-finger transistor generally includes a plurality of gates having finger shapes disposed on a substrate in parallel. The gates are electrically connected and source/drain regions are disposed at portions of the substrate between the gates. The source/drain regions are connected to wirings, respectively.

The RF characteristics of the multi-finger transistor may be varied by a distance between gates, structures of wirings connected to source/drain regions, positions of gates on a substrate, etc. Thus, a layout of elements in the multi-finger transistor may provide desired RF characteristics of the multi-finger transistor.

To reduce a generation of a noise through a substrate, a conventional multi-finger transistor includes a substrate contact and a conductive line connected to the substrate contact. The conductive line is further electrically connected to a ground. The conductive line usually has a ring shape that fully encloses the gate fingers and the source/drain regions of the multi-finger transistor. For example, Japanese Laid-Open Patent Publication No. 2006-147756 discloses a multi-finger transistor having a substrate contact and a ring-shaped conductive line.

However, a parasitic capacitance may be generated between the substrate and the gate fingers by the ring-shaped conductive line. The parasitic capacitance may reduce cut-off frequency characteristics of the multi-finger transistor. Further, the parasitic capacitance may become more serious in the multi-finger transistor because a distance between the conductive line and the gate fingers may greatly decrease as the multi-finger transistor is more highly integrated. As a result, the conventional multi-finger transistor may not ensure sufficient RF characteristics for various communication systems.

### SUMMARY

According to one aspect of example embodiments, there is provided a multi-finger transistor including gate fingers disposed on a substrate, at least one gate wiring connected to end portions of the gate fingers and source regions and drain regions in the substrate, disposed between the gate fingers. A conductive line partially encloses the gate fingers and the gate wiring. The conductive line does not fully enclose the gate fingers and the gate wiring. Substrate plugs electrically connect the conductive line to the substrate. The conductive line is separated from the gate fingers and the gate wiring.

In example embodiments, the at least one gate wiring may include a first gate wiring connected to first end portions of the gate fingers, and a second gate wiring connected to second end portions of the gate fingers.

In some example embodiments, the at least one gate wiring may include gate contacts contacting the end portions of the gate fingers, and a gate line connected to the gate contacts.

In example embodiments, the conductive line may include a first portion substantially parallel to the gate fingers, and second portions substantially parallel to the gate wiring.

In other example embodiments, the conductive line may include a first portion substantially parallel to the gate wiring, and second portions substantially parallel to the gate fingers.

In some example embodiments, the conductive line may include a first portion substantially parallel to one of the gate wiring or the gate fingers, and a second portion substantially parallel to another of the gate fingers or the gate wiring.

In example embodiments, the source regions and the drain regions may be alternately disposed between the gate fingers.

In example embodiments, the multi-finger transistor may additionally include a source wiring for electrically connecting the source regions, and a drain wiring electrically connecting the drain regions. The source wiring may include source contacts electrically contacting the source regions and a source connection line connected to the source contacts. The drain wiring may include drain contacts electrically contacting the drain regions and a drain connection line connected to the drain contacts.

In other example embodiments, the conductive line is a U-shaped or an L-shaped conductive line.

According to another aspect of example embodiments, there is provided a multi-finger transistor including a plurality of gate fingers disposed to cross an active region of a substrate, a plurality of gate contacts connected to end portions of the gate fingers, at least one gate line electrically connected to the gate contacts and a plurality of source regions and drain regions alternately disposed in the substrate between the gate fingers. A conductive line partially encloses the gate fingers and the gate line. The conductive line does not fully enclose the gate fingers and the gate line. A plurality of substrate plugs electrically connect the conductive line to the substrate. The conductive line is separated from the gate fingers and the gate line. In some embodiments, the substrate plugs are regularly arranged (i.e., equally spaced apart) on the substrate.

In example embodiments, the multi-finger transistor may additionally include a source wiring and a drain wiring. The source wiring may have source contacts connected to the source regions and a source connection line connected to the source contacts. The drain wiring may have drain contacts connected to the drain regions and a drain connection line connected to the drain contacts.

In example embodiments, the multi-finger transistor may further include a first insulation interlayer disposed between the gate fingers and the at least one gate line. The gate contacts may extend through the first insulation interlayer.

In example embodiments, the multi-finger transistor may further include a second insulation layer disposed between the at least one gate line and the conductive line. The substrate plugs may extend through the first and the second insulation interlayers.

In example embodiments, the multi-finger transistor may further include a third insulation interlayer disposed between the conductive line and the source and the drain wirings. The source and the drain contacts may extend through the first, the second and the third insulation interlayers.

In example embodiments, the conductive line may include a first portion extending substantially parallel to one of the gate fingers or the at least one gate line, and a second portion extending substantially parallel to another of the at least one gate line or the gate fingers.

In other example embodiments, the conductive line may be a U-shaped or an L-shaped conductive line.

According to still another aspect of example embodiments, there is provided a semiconductor device including a substrate having a digital circuit area and an analog circuit area, and multi-finger transistors arranged in the analog circuit area. Multi-finger transistors are continuously disposed at a peripheral portion of the analog circuit area. Here, each of the multi-finger transistors may include gate fingers disposed on the analog circuit area; at least one gate wiring connected to end portions of the gate fingers; source regions and drain regions disposed between the gate fingers; a conductive line partially enclosing the gate fingers and the gate wiring; and substrate plugs electrically connecting the conductive line to the substrate. The conductive line does not fully enclose the gate fingets and the gate wiring. The conductive line may have a U shape or an L shape.

According to still another aspect of example embodiments, there is provided methods of forming a multi-finger transistor. In these methods, gate fingers are formed on a substrate, and at least one gate wiring connected to end portions of the gate fingers is formed. Source regions and drain regions are formed between the gate fingers. A conductive line is formed to partially enclose the gate fingers and the gate wiring. The conductive line does not fully enclose the gate fingers and the gate wiring. The conductive line is separated from the gate fingers and the gate wiring. The conductive line may have a U shape or an L shape. Substrate plugs are formed to electrically connect the conductive line to the substrate.

In a formation of the at least one gate wiring according to example embodiments, gate contacts connected to the end portions of the gate fingers may be formed, and then at least one gate line connected to the gate contacts may be formed.

In example embodiments, source contacts connected to the source regions may be formed, and drain contacts connected to the drain regions may be formed. A source connection line connected to the source contacts may be formed, and a drain connection line connected to the drain contacts may be formed.

According to example embodiments, the conductive line and the substrate plugs may partially enclose a portion of the substrate on which the gate fingers and the gate wiring(s) are provided. The conductive line and the substrate plugs may not fully enclose the portion of the substrate on which the gate fingers and the gate wiring(s) are provided. Therefore, parasitic capacitances caused by the conductive line and the substrate plugs may be considerably reduced, which can improve high radio frequency characteristics of the multi-finger transistor. Further, sizes of the conductive line and the substrate plugs may be reduced, so that the multi-finger transistor may have more enhanced integration degree. Furthermore, parasitic capacitances generated between the substrate and the gate fingers may be greatly reduced, which can improve high maximum oscillation characteristics of the multi-finger transistor.

### BRIEF DESCRIPTION OF THE DRAWINGS

Example embodiments will be will become more apparent by describing in detailed thereof with reference to the accompanying drawings, in which:

FIG. 1 is a plan view illustrating a multi-finger transistor in accordance with example embodiments;

FIGS. 2 to 5 are plan views illustrating methods of manufacturing a multi-finger transistor in accordance with example embodiments;

FIG. 6 is a plan view illustrating a multi-finger transistor in accordance with example embodiments;

FIG. 7 is a plan view illustrating a multi-finger transistor in accordance with example embodiments;

FIG. 8 is a plane view illustrating a semiconductor substrate having multi-finger transistors in accordance with example embodiments;

FIG. 9 is a plan view illustrating a multi-finger transistor in accordance with example embodiments; and

FIG. 10 is a plan view illustrating a conventional multi-finger transistor according to comparative embodiments.

### DESCRIPTION OF EMBODIMENTS

The example embodiments are described more fully hereinafter with reference to the accompanying drawings. The invention may, however, be embodied in many different forms and should not be construed as limited to the example embodiments set forth herein. Rather, these example embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer (and variants thereof), it can be directly on, connected or coupled to the other element or layer or intervening elements or layers may be present. In contrast, when an element is referred to as being “directly on,” “directly connected to” or “directly coupled to” another element or layer (and variants thereof), there are no intervening elements or layers present. Like or similar reference numerals refer to like or similar elements throughout. As used herein, the term “and/or” includes any and all combinations of one or more of the associated listed items.

It will be understood that, although the terms first, second, third etc. may be used herein to describe various elements, components, regions, layers, patterns and/or sections, these elements, components, regions, layers, patterns and/or sections should not be limited by these terms. These terms are only used to distinguish one element, component, region, layer pattern or section from another region, layer, pattern or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly. Thus, for example, a U-shape may be regarded as a C-shape, depending on orientation.

The terminology used herein is for the purpose of describing particular example embodiments only and is not intended to be limiting of the invention. As used herein, the singular forms “a,” “an” and “the” are intended to include the plural forms as well, unless the context clearly indicates otherwise. It will be further understood that the terms “comprising,” “including,” and or “having”, and variants thereof, when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of illustratively idealized example embodiments (and intermediate structures) of the invention. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

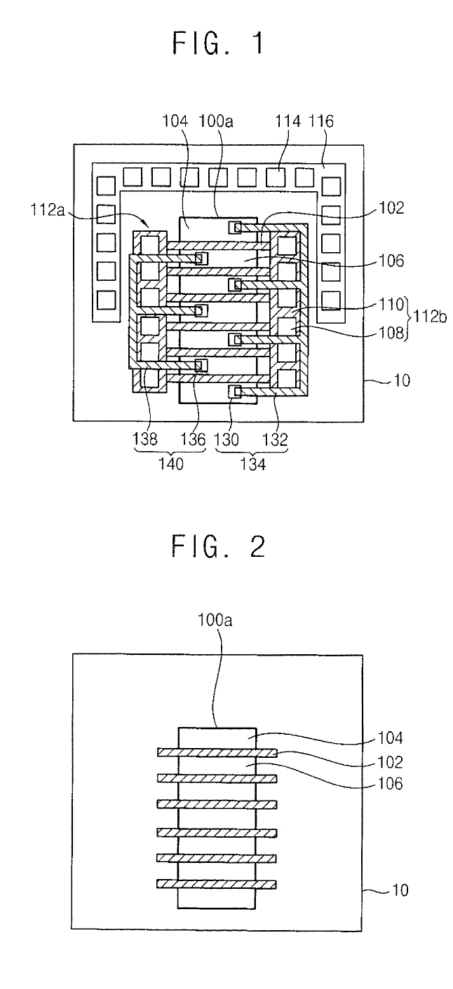

FIG. 1 is a plan view illustrating a multi-finger transistor in accordance with example embodiments.

Referring to FIG. 1, a substrate 10 having an active region 100a and an isolation region is provided. The substrate 10 may include a bulk semiconductor material. For example, the substrate 10 may include a silicon substrate, a germanium substrate, a silicon-germanium substrate, etc. Alternatively, the substrate 10 may include a multilayer substrate such as a silicon-on-insulator (SOI) substrate or a germanium-on-insulator (GOI) substrate.

The active region 100a of the substrate 10 may be defined by forming an isolation layer on the substrate 10. The isolation layer may be formed by a shallow trench isolation (STI) process or a thermal oxidation process. The isolation layer may include an oxide such as silicon oxide. For example, the isolation layer may be formed using undoped silicate glass (USG), spin on glass (SOG), boro silicate glass (BSG), phosphor silicate glass (PSG), boro-phosphor silicate glass (BPSG), flowable oxide (FOX), tetra ethyl ortho silicate (TEOS), plasma enhanced-tetra ethyl ortho silicate (PE-TEOS), high density plasma-chemical vapor deposition (HDP-CVD) oxide, etc.

In example embodiments, a portion of the substrate 10 enclosed by the isolation layer may correspond to the active regions 100a whereas a portion of the substrate 10 on which the isolation layer is formed may correspond to the isolation region. A well may be formed in the active region 100a by doping impurities into the substrate 10. The well may have a P-type conductivity or an N-type conductivity in accordance with the types of the impurities.

Gate fingers 102 may be provided on the substrate 10. The gate fingers 102 may cross over the active region 100a. Each of the gate fingers 102 may include a gate insulation layer pattern and a gate electrode. The gate fingers 102 may have line structures extending on the substrate 10 along a first direction (illustrated as horizontal). Additionally, a plurality of gate fingers 102 may be arranged on the substrate 10 in a second direction. For example, the second direction may be substantially perpendicular to the first direction.

In example embodiments, the gate insulation layer pattern may include an oxide or a metal oxide. For example, the gate insulation layer may include silicon oxide, titanium oxide (TiOx), aluminum oxide (AlOx), hafnium oxide (HfOx), tantalum oxide (TaOx), etc. These may be used alone or in a combination/subcombination thereof. Further, the gate electrode may be formed using polysilicon, a metal and/or a metal compound. For example, the gate electrode may include polysilicon doped with impurities, titanium (Ti), tungsten (W), tantalum (Ta), aluminum (Al), copper (Cu), tungsten nitride (WNx), titanium nitride (TiNx), aluminum nitride (AlNx), titanium aluminum nitride (TiAlxNy), tantalum nitride (TaNx), tungsten silicide (WSix), titanium silicide (TiSix), cobalt silicide (CoSix), etc. These may be used alone or in a combination/subcombination thereof.

In example embodiments, a width of a multi-finger transistor may be substantially the same as the sum of widths of the gate fingers 102. That is, the width of the multi-finger transistor may be obtained by multiplying the number of the gate fingers 102 by a width of each of the gate fingers 102. When the number of the gate fingers 102 increases, the multi-finger transistor may have an increased effective area, thereby increasing a driving current of the multi-finger transistor.

Referring now to FIG. 1, source/drain regions 104 and 106 are formed at portions of the active region 100a between adjacent gate fingers 102. In example embodiments, a plurality of source regions 104 and a plurality of drain regions 106 may be alternately disposed between the gate fingers 102. The source/drain regions 104 and 106 may be formed by an ion implantation process.

A first insulation interlayer (not illustrated) is provided on the substrate 10 to cover the gate fingers 102. The first insulation interlayer may include an oxide. For example, the first insulation interlayer may include USG, SOG, PSG, BPSG, FOX, TEOS, PE-TEOS, HDP-CVD oxide, etc.

A first gate wiring 112a and a second gate wiring 112b are disposed on the first insulation interlayer. The first and the second wirings 112a and 112b may be provided for electrical connections among the gate fingers 102. For example, first end portions of the gate fingers 102 may be electrically connected by the first gate wiring 112a, and second end portions of the gate fingers 102 may be electrically connected through the second gate wiring 112b. Each of the first and the second gate wirings 112a and 112b may include polysilicon, a metal and/or a metal compound. For example, the first and the second gate wirings 112a and 112b may include polysilicon doped with impurities, titanium, tungsten, tantalum, aluminum, copper, tungsten nitride, titanium nitride, aluminum nitride, titanium aluminum nitride, tantalum nitride, tungsten silicide, titanium silicide, cobalt silicide, etc. These may be used alone or in a combination/subcombination thereof.

In example embodiments, the first gate wiring 112a may be substantially parallel to the second gate wiring 112b. Further, the first gate wiring 112a may have a structure substantially the same or substantially similar to that of the second gate wiring 112b. Since the gate fingers 102 are electrically connected by the first and the second gate wirings 112a and 112b, the gate fingers 102 may operate as one gate such as a multi-finger gate.

The first and the second gate wirings 112a and 112b include gate contacts 108 and gate lines 110, respectively. The gate contacts 108 may pass through the first insulation interlayer and may electrically contact the first and the second end portions of the gate fingers 102. The gate contacts 108 may be electrically connected each other by the gate lines 110 on the first insulation interlayer. When the first and the second end portions of the gate fingers 102 are electrically connected through the first and the second gate wirings 112a and 112b, the gate having such construction may be referred to as a folded type gate.

In some example embodiments, the first and the second gate wirings 112a and 112b may be disposed in a plane where the gate fingers 102 are arranged. Namely, the gate fingers 102, the first gate wirings 112a, and the second gate wiring 112b may be formed on the substrate 10. Here, the first and the second gate wirings 112a and 112b may have pattern structures being connected to the first and the second end portions of the gate fingers 102, respectively.

A second insulation interlayer (not illustrated) is provided on the first insulation interlayer to cover the first and the second gate wirings 112a and 112b. The second insulation interlayer may include an oxide such as silicon oxide. For example, the second insulation interlayer may include USG, SOG, TEOS, PE-TEOS, PSG, BPSG, FOX, HDP-CVD oxide, etc. The second insulation interlayer may include oxide substantially the same as or substantially similar to that of the first insulation interlayer. Alternatively, the first and the second insulation interlayers may include different oxides, respectively.

A conductive line 116 is disposed on the second insulation interlayer. The conductive line 116 may include polysilicon, a metal and/or a metal compound. For example, the conductive line 116 may include polysilicon doped with impurities, titanium, tungsten, tantalum, aluminum, copper, tungsten nitride, titanium nitride, aluminum nitride, titanium aluminum nitride, tantalum nitride, tungsten silicide, titanium silicide, cobalt silicide, etc. These may be used alone or in a combination/subcombination thereof. In example embodiments, the conductive line 116 may be separated (i.e., spaced-apart) from the gate fingers 102, the first gate wiring 112a and the second gate wiring 112b by a predetermined distance. Further, the conductive line 116 may partially enclose, but not fully enclose, a predetermined portion of the substrate 10 where the gate fingers 102, the first gate wiring 112a and the second gate wiring 112b are disposed. For example, the conductive line 116 may generally have a U-shaped construction. Further, one conductive line 116 may be included in the multi-finger transistor having the plurality of gate fingers 102.

Substrate plugs 114 are provided through the second and the first insulation interlayers. The substrate plugs 114 may be electrically connected to the conductive line 116. Each of the substrate plugs 114 may make contact with the substrate 10. The substrate plugs 114 may be arranged by a predetermined interval. That is, in some embodiments, adjacent substrate plugs 114 may be equally spaced apart from one another.

In example embodiments, each of the substrate plugs 114 may include doped polysilicon, a metal and/or a metal compound. For example, the substrate plugs 114 may include polysilicon doped with impurities, titanium, tungsten, tantalum, aluminum, copper, tungsten nitride, titanium nitride, aluminum nitride, titanium aluminum nitride, tantalum nitride, etc. These may be used alone or in a combination/subcombination thereof. The substrate plugs 114 may have multi layer structures. For example, first portions of the substrate plugs 114 in the first insulation interlayer may include doped polysilicon, and second portions of the substrate plugs 114 may include metal and/or metal compound.

In example embodiments, the substrate plugs 114 may be grounded, so that the conductive line 116 contacting the substrate plugs 114 may also be grounded. Therefore, generation of a noise caused through the substrate 10 may be reduced or prevented because the conductive line 116 and the substrate plugs 114 are grounded.

A third insulation interlayer (not illustrated) is disposed on the second insulation interlayer to cover the conductive line 116. The third insulation layer may include an oxide such as USG, SOG, TEOS, PE-TEOS, PSG, BPSG, FOX, HDP-CVD oxide, etc.

A source wiring 134 is provided on the third insulation interlayer. The source regions 104 are electrically connected by the source wiring 134. The source wiring 134 includes source contacts 130 and a source connection line 132. The source contacts 130 make contact with the source regions 104, respectively. The source contacts 130 are electrically connected to the source connection line 132. Each of the source contacts 130 may be formed through the third, the second and the first insulation interlayers. Here, the source connection line 132 may be positioned on the third insulation interlayer.

The source contacts 130 may include polysilicon, a metal and/or a metal compound. For example, the source contacts 130 may include polysilicon doped with impurities, titanium, tungsten, tantalum, aluminum, copper, tungsten nitride, titanium nitride, aluminum nitride, titanium aluminum nitride, tantalum nitride, etc. These may be used alone or in a combination/subcombination thereof. Further, the source connection line 132 may also include polysilicon, a metal and/or a metal compound. For example, the source connection line 132 may include polysilicon doped with impurities, titanium, tungsten, tantalum, aluminum, copper, tungsten nitride, titanium nitride, aluminum nitride, titanium aluminum nitride, tantalum nitride, tungsten silicide, titanium silicide, cobalt silicide, etc. These may be used alone or in a combination/subcombination thereof.

In example embodiments, the source connection line 132 includes a first portion and second portions divided from the first portion. The first portion of the source connection line 132 may be disposed substantially parallel to the second gate wiring 112b, and the second portions of the source connection line 132 may be substantially parallel to the gate fingers 102. The second portions of the source connection line 132 may be connected to the source contacts 130, respectively. Therefore, the plurality of source regions 104 may serve as one source region of the multi-finger transistor.

A drain wiring 140 is provided on the third insulation interlayer. The drain wiring 140 may be configured substantially similar to the source wiring 134. The drain regions 106 are electrically connected by the drain wiring 140. The drain wiring 140 includes drain contacts 136 and a drain connection line 138. The drain contacts 136 make contact with the drain regions 106, respectively. The drain contacts 136 are electrically connected to the drain connection line 138. The drain contacts 136 may be formed through the third, the second and the first insulation interlayers, and the drain connection line 138 may be located on the third insulation interlayer. The drain contacts 136 may also include polysilicon, a metal and/or a metal compound. For example, the drain contacts 136 may include polysilicon doped with impurities, titanium, tungsten, tantalum, aluminum, copper, tungsten nitride, titanium nitride, aluminum nitride, titanium aluminum nitride, tantalum nitride, etc. These may be used alone or in a combination/subcombination thereof. Additionally, the drain connection line 138 may include polysilicon, a metal and/or a metal compound. For example, the drain connection line 138 may include polysilicon doped with impurities, titanium, tungsten, tantalum, aluminum, copper, tungsten nitride, titanium nitride, aluminum nitride, titanium aluminum nitride, tantalum nitride, tungsten silicide, titanium silicide, cobalt silicide, etc. These may be used alone or in a combination/subcombination thereof.

In example embodiments, the drain connection line 138 also has a first portion and second portions divided from the first portion. The first portion of the drain connection line 138 may be disposed substantially parallel to the first gate wiring 112a, and the second portions of the drain connection line 138 may be substantially parallel to the gate fingers 102. The second portions of the drain connection line 138 may be connected to the drain contacts 136, respectively. Thus, the plurality of drain regions 106 may also serve as one drain region of the multi-finger transistor.

According to example embodiments, the conductive line 116 and the substrate plugs 114 may partially, but not fully, enclose the portion of the substrate 10 on which the gate fingers 102 and the gate wirings 112a and 112b are provided. The conductive line 116 may be U-shaped, as illsutrated. Thus, parasitic capacitances caused by the conductive line 116 and the substrate plugs 114 may be considerably reduced to thereby allow high cut-off frequency characteristics of the multi-finger transistor. Additionally, sizes of the conductive line 116 and the substrate plugs 114 may be reduced, so that the multi-finger transistor may have more enhanced integration degree. Furthermore, parasitic capacitances generated between the substrate 10 and the gate fingers 102 may be greatly reduced to thereby allow improved high maximum oscillation characteristics of the multi-finger transistor.

FIGS. 2 to 5 are plan views illustrating methods of manufacturing a multi-finger transistor in accordance with example embodiments.

Referring to FIG. 2, an isolation layer (not illustrated) is formed on a substrate 10 such as a silicon substrate, a germanium substrate, a silicon-germanium substrate, an SOI substrate, a GOI substrate, etc. The isolation layer may be formed using silicon oxide such as USG, SOG, BPSG, PSG, BSG, FOX, TEOS, PE-TEOS, HDP-CVD oxide, etc. Further, the isolation layer may be formed by a thermal oxidation process, a chemical vapor deposition (CVD) process, a plasma enhanced chemical vapor deposition (PECVD) process, an HDP-CVD process, etc.

In example embodiments, the substrate 10 may be partially etched to provide a trench thereon, and then the trench may be filled with oxide to form the isolation layer in the trench. When the isolation layer is formed on the substrate 10, an active region 100a and an isolation region are defined. For example, a portion of the substrate 10 on which the isolation layer is provided may correspond to the isolation region whereas a portion of the substrate 10 enclosed by the isolation layer may correspond to the active region 100a.

A gate insulation layer (not illustrated) and a gate conductive layer (not illustrated) are sequentially formed on the substrate 10. The gate insulation layer may be formed using an oxide or a metal oxide, and the gate conductive layer may be formed using polysilicon, a metal and/or a metal compound. For example, the gate insulation layer may include silicon oxide, hafnium oxide, titanium oxide, tantalum oxide, tantalum oxide, etc. Additionally, the gate conductive layer may be formed using polysilicon doped with impurities, tungsten, titanium, aluminum, tantalum, copper, tungsten nitride, aluminum nitride, titanium nitride, titanium aluminum nitride, tantalum nitride, tungsten silicide, titanium silicide, tantalum silicide, cobalt silicide, etc. These may be used alone or in a combination/subcombination thereof.

The gate insulation layer may be formed by a thermal oxidation process, a chemical vapor deposition (CVD) process, an atomic layer deposition (ALD) process, a sputtering process, an evaporation process, etc. Further, the gate conductive layer may be formed by an ALD process, a CVD process, a sputtering process, an evaporation process, a pulsed laser deposition (PLD) process, etc. In example embodiments, the gate conductive layer may have a single layer structure or a multi-layer structure. For example, the gate conductive layer may have at least one of a polysilicon film, a metal film, a metal nitride film and a metal silicide film.

The gate conductive layer and the gate insulation layer are etched to form a plurality of gate fingers 102 on the substrate 10. The gate fingers 102 may have line structures, respectively. Each of the gate fingers 102 includes a gate insulation layer pattern and a gate electrode. The gate fingers 102 may run across the active region 100a. The gate fingers 102 may extend on the substrate along a first direction, and the active region 100a may extend in a second direction substantially perpendicular to the first direction. The plurality of gate fingers 102 may be separated by a substantially equal distance.

Using the gate fingers 102 as implantation masks, impurities are doped into the active region 100a to form a plurality of source regions 104 and a plurality of drain regions 106. The source regions 104 and the drain regions 106 may be alternately disposed at portions of the active region 100a between adjacent gate fingers 102.

A first insulation interlayer (not illustrated) is formed on the substrate 10 to cover the gate fingers 102. The first insulation interlayer may be formed using an oxide such as silicon oxide. For example, the first insulation interlayer may include USG, SOG, TEOS, PE-TEOS, PSG, BPSG, FOX, HDP-CVD oxide, etc. Further, the first insulation interlayer may be formed by an HDP-CVD process, a spin coating process, a CVD process, a low pressure chemical vapor deposition (LPCVD) process, a PECVD process, etc.

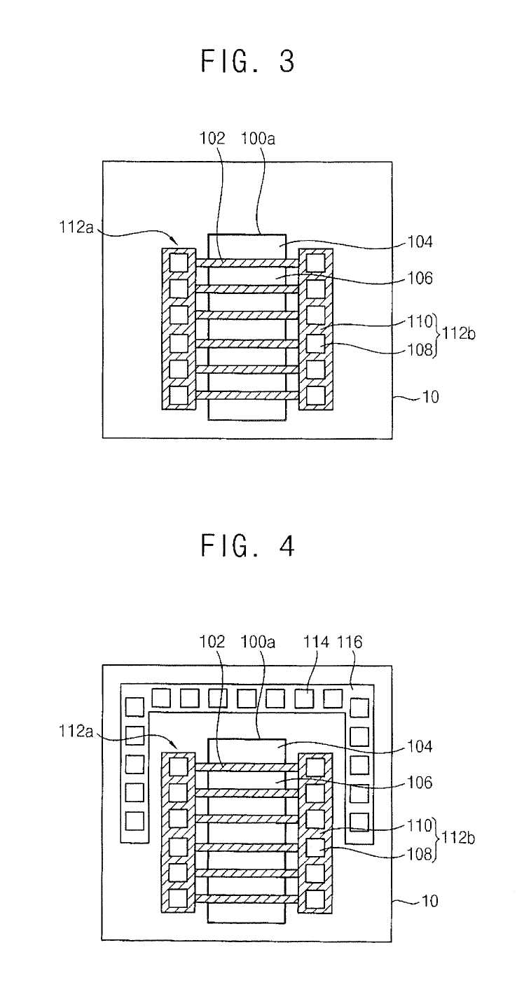

Referring to FIG. 3, the first insulation interlayer is partially etched to form gate contact holes that expose the gate fingers 102, respectively. In example embodiments, first and second end portions of the gate fingers 102 may be exposed through the gate contact holes. The gate contact holes may be formed by an anisotropic etching process.

A first conductive layer (not illustrated) is formed on the first insulation layer to fill the gate contact holes, and then the first conductive layer is partially removed until the first insulation interlayer is exposed. Thus, gate contacts 108 filling the gate contact holes are provided on the exposed portions of the gate fingers 102. The first conductive layer may be formed using polysilicon, a metal and/or a metal compound through a sputtering process, a CVD process, an ALD process, an evaporation process, a PLD process, etc. For example, the first conductive layer may be formed using polysilicon doped with impurities, tungsten, titanium, aluminum, tantalum, tungsten nitride, aluminum nitride, titanium nitride, tantalum nitride, etc. Further, the gate contacts 108 may be formed by a chemical mechanical polishing (CMP) process and/or an etch-back process.

In some example embodiments, lower substrate pads contacting portions of the substrate 10 may be formed through the first insulation interlayer while forming the gate contacts 108. That is, the lower substrate pads may be formed by partially removing the first conductive layer after forming lower substrate contact holes through the first insulation interlayer.

Gate lines 110 are formed on the first insulation interlayer. The gate lines 110 may make electrical contact with the gate contacts 108 and may extend along the second direction. The gate lines 110 may be formed by patterning a second conductive layer after forming the second conductive layer on the first insulation interlayer. Here, the second conductive layer may be formed using polysilicon, a metal and/or a metal compound by a sputtering process, an ALD process, a CVD process, an evaporation process, a PLD process, etc. For example, the second conductive layer may include polysilicon doped with impurities, tungsten, titanium, aluminum, tantalum, tungsten nitride, aluminum nitride, titanium nitride, tantalum nitride, tungsten silicide, titanium silicide, cobalt silicide, tantalum silicide, etc. These may be used alone or in a combination/subcombination thereof.

In example embodiments, two gate lines 110 may be formed on the first insulation interlayer. The gate lines 110 may be arranged substantially in parallel on the first insulation interlayer. When the gate lines 110 are provided on the first insulation interlayer, a first gate wiring 112a and a second gate wiring 112b are formed over the substrate 10. The first gate wiring 112a includes some of the gate contacts 108 contacting the first end portions of the gate fingers 102, and one of the gate lines 110 electrically connected to the first end portions of the gate fingers 102. The second gate wiring 112b includes others of the gate contacts 110 contacting the second end portions of the gate fingers 102, and the other of the gate lines 110 electrically connected to the second end portions of the gate fingers 102.

A second insulation interlayer (not illustrated) is provided on the first insulation interlayer to cover the first and the second gate wirings 112a and 112b. The second insulation interlayer may be formed using silicon oxide by a CVD process, an HDP-CVD process, an LPCVD process, a PECVD process, a spin coating process, etc. For example, the second insulation interlayer may include USG, SOG, FOX, TEOS, PE-TEOS, PSG, BPSG, HDP-CVD oxide, etc.

Referring to FIG. 4, the second insulation interlayer and the first insulation interlayer are partially etched to form substrate contact holes that expose predetermined portions of the substrate 10. The substrate contact holes may be arranged to partially enclose the first gate wiring 112a, the second gate wiring 112b and the gate fingers 102. The substrate contact holes may be formed through the first and the second insulation interlayers by an anisotropic etching process.

After a third conductive layer (not illustrated) is formed on the second insulation interlayer to fill the substrate contact holes, the third conductive layer is partially removed until the second insulation interlayer is exposed. Hence, substrate pads 114 filling the substrate contact holes are provided on the exposed portions of the substrate. The third conductive layer may be formed using polysilicon, a metal and/or a metal nitride by a sputtering process, an ALD process, a CVD process, an evaporation process, a PLD process, etc. For example, the third conductive layer may include doped polysilicon, tungsten, titanium, aluminum, tantalum, tungsten nitride, aluminum nitride, titanium nitride, tantalum nitride, etc. These may be used alone or in a combination/subcombination thereof. Further, the substrate pads 114 may be formed by a CMP process and/or en etch-back process.

When the lower substrate pads are provided through the first insulation interlayer, upper substrate pads may be formed through the second insulation layer, so that the substrate pads 114 having the lower and the upper substrate pads may be formed through the first and the second insulation interlayers.

A conductive line 116 making contact with the substrate pads 114 is formed on the second insulation layer. The conductive line 116 may be formed by patterning a fourth conductive layer after forming the fourth conductive layer on the second insulation interlayer. Here, the fourth conductive layer may be formed using a metal, a metal compound and/or polysilicon by a sputtering process, an ALD process, a CVD process, an evaporation process, a PLD process, etc. For example, the fourth conductive layer may include doped polysilicon, tungsten, titanium, aluminum, tantalum, tungsten nitride, aluminum nitride, titanium nitride, tantalum nitride, tungsten silicide, tantalum silicide, titanium silicide, cobalt silicide, etc. These may be used alone or in a combination/subcombination thereof. The conductive line 116 may include a conductive material substantially the same as or substantially similar to those of the substrate pads 114.

In example embodiments, the conductive line 116 may partially but not fully enclose the first gate wiring 112a, the second gate wiring 112b and the gate fingers 102 by a predetermined interval. For example, the conductive line 116 may have a U-shape that partially, but not fully, encloses the first gate wiring 112a, the second gate wiring 112b and the gate fingers 102 on a plane. Here, end portions of the conductive line 116 may be substantially parallel relative to the gate lines 110 whereas a central portion of the conductive line 116 may be substantially parallel with respect to the gate fingers 102.

In some example embodiments, lower source contacts and lower drain contacts may be formed through the first and the second insulation interlayers while forming the substrate pads 114. That is, the lower source and drain contacts may be formed in lower source and drain contact holes after forming the lower source and drain contact holes through the first and the second insulation interlayers. The lower source and drain contacts may make contact with the source and the drain regions 104 and 106, respectively.

A third insulation interlayer (not illustrated) is formed on the second insulation interlayer to cover the conductive line 116. The third insulation interlayer may be formed using an oxide by a CVD process, a PECVD process, an LPCVD process, an HDP-CVD process, a spin coating process, etc. For example, the third insulation interlayer may include USG, SOG, BPSG, PSG, FOX, TEOS, PE-TEOS, HDP-CVD oxide, etc.

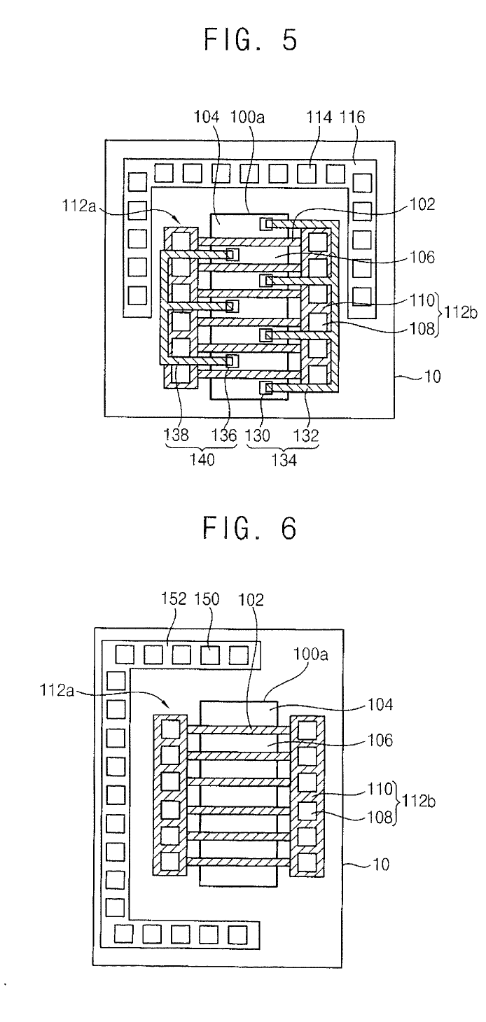

Referring to FIG. 5, source contact holes and drain contact holes are formed through the third, the second and the first insulation interlayers by partially etching the third to the first insulation interlayers. The source and the drain contact holes may partially expose the source and the drain regions 104 and 106, respectively. The source and the drain contact holes may be formed by an anisotropic etching process.

A fifth conductive layer is formed on the third insulation interlayer, and then the fifth conductive layer is partially removed until the third insulation interlayer is exposed. Thus, source and drain contacts 130 and 136 are formed in the source and the drain contact holes. The fifth conductive layer may be formed using a metal, a metal compound and/or polysilicon by a sputtering process, an ALD process, a CVD process, an evaporation process, a PLD process, etc. For example, the fifth conductive layer may include doped polysilicon, tungsten, titanium, aluminum, tantalum, tungsten nitride, aluminum nitride, titanium nitride, tantalum nitride, etc. These may be used alone or in a combination/subcombination thereof. The source and the drain contacts 130 and 136 may be formed by a CMP process and/or an etch-back process.

A source connection line 132 and a drain connection line 138 are formed on the third insulation interlayer. The source and the drain connection lines 132 and 138 may be formed by patterning a sixth conductive layer after forming the sixth conductive layer on the third insulation interlayer. Here, the sixth conductive layer may be formed using a metal, a metal compound and/or polysilicon by a sputtering process, an ALD process, a CVD process, an evaporation process, a PLD process, etc. For example, the fourth conductive layer may include doped polysilicon, tungsten, titanium, aluminum, tantalum, tungsten nitride, aluminum nitride, titanium nitride, tantalum nitride, cobalt silicide, titanium silicide, tantalum silicide, tungsten silicide, etc. These may be used alone or in a combination/subcombination thereof.

The source and the drain connection lines 132 and 138 make contact with the source and the drain contacts 130 and 136, respectively. First portions of the source connection line 132 may contact the source contacts 130, and the first portions may be divided from a second portion of the source connection line 132. The first portions of the source connection line 132 may substantially parallel to the gate fingers 102, and the second portion of the source connection line 132 may substantially parallel to the gate lines 110. Additionally, the drain connection line 138 may also have first portions and a second portion. The first portions of the drain connection line 138 are divided from the second portion of the drain connection line 138. The first portions of the drain connection line 138 may make contact with the drain contacts 136. The second portion of the drain connection line 138 may be substantially parallel to the gate fingers 102, and the first portions of the drain connection line 138 may be substantially parallel to the gate lines 110.

According to example embodiments, the substrate pads 114 and the conductive line 116 may partially, but not fully, enclose a portion of the substrate 10 where the gate fingers 102, the first gate wiring 112a and the second gate wiring 112b. Therefore, parasitic capacitances among the substrate pads 114, the conductive line 116, the gate fingers 102, the first gate wiring 112a and the second gate wiring 112b may be considerably reduced to thereby allow improved RF characteristics of the multi-finger transistor whereas a generation of a noise through the substrate 10 may be effectively reduced.

FIG. 6 is a plan view illustrating a multi-finger transistor in accordance with other example embodiments. In FIG. 6, the multi-finger transistor may have a construction substantially the same as or substantially similar to that of the multi-finger transistor described with reference to FIG. 1 except positions of substrate pads 150 and a conductive line 152.

Referring to FIG. 6, the multi-finger transistor includes gate fingers 102, source regions 104, drain regions 106, a first gate wiring 112a, a second gate wiring 112b, the substrate pads 150 and the conductive line 152.

The gate fingers 102 are disposed on a substrate 10 having an active region 100a. The substrate 10 may include a semiconductor material. An isolation layer (not illustrated) is provided on the substrate 10 to define the active region 100a and an isolation region. The gate fingers 102 may have line structures crossing the active regions 100a. The gate fingers 102 may include doped polysilicon, metal and/or metal nitride. Each of the gate fingers 102 includes a gate insulation layer pattern and a gate electrode. The gate insulation layer pattern may include oxide or metal oxide, and the gate electrode may include polysilicon, metal and/or metal compound.

A plurality of source regions 104 and a plurality of drain regions 106 are disposed at portions of the active region 100a between the gate fingers 102. The source and the drain regions 104 and 106 may be alternately arranged on the active region 100a.

The first and the second gate wiring 112a and 112b are disposed on a first insulation interlayer (not illustrated) covering the gate fingers 102. First end portions of the gate fingers 102 may be electrically connected each other by the first gate wiring 112a, and second end portions of the gate fingers 102 may be electrically connected each other through the second gate wiring 112b. The first and the second gate wirings 112a and 112b may include polysilicon, metal and/or metal compound. The first gate wiring 112a may have a structure substantially the same or substantially similar to that of the second gate wiring 112b.

The first and the second gate wirings 112a and 112b include gate contacts 108 and gate lines 110, respectively. The gate contacts 108 may be formed through the first insulation interlayer and may be electrically connected to the first and the second end portions of the gate fingers 102. The gate contacts 108 may be electrically connected each other by the gate lines 110.

The conductive line 152 is disposed on a second insulation interlayer (not illustrated) covering the first and the second gate wirings 112a and 112b. The conductive line 152 may include doped polysilicon, metal and/or metal compound. The conductive line 152 may be separated from the gate fingers 102, the first gate wiring 112a and the second gate wiring 112b.

In example embodiments, the conductive line 152 may partially, but not fully, enclose a predetermined portion of the substrate 10 on which the gate fingers 102, the first gate wiring 112a and the second gate wiring 112b are formed. For example, the conductive line 152 may generally have a U-shaped construction. Further, one conductive line 152 may be included in the multi-finger transistor having the plurality of gate fingers 102. The conductive line 152 has a central portion and end portions. The central portion of the conductive line 152 may be substantially parallel to the first and the second gate wirings 112a and 112b. The end portions of the conductive line 152 may be substantially parallel with respect to the gate fingers 102.

The substrate plugs 150 are provided through the second and the first insulation interlayers. The substrate plugs 150 contacting the substrate 10 may be electrically connected to the conductive line 152. The substrate plugs 150 may include doped polysilicon, metal and/or metal compound. The substrate plugs 150 may be grounded, and thus the conductive line 152 contacting the substrate plugs 150 may also be grounded. Hence, a generation of a noise caused through the substrate 10 may be reduced or prevented because the conductive line 152 and the substrate plugs 150 are grounded.

In example embodiments, the multi-finger transistor further includes a source wiring (not illustrated) and a drain wiring (not illustrated) provided on a third insulation interlayer (not illustrated) covering the conductive line 152. The source regions 104 may be electrically connected by the source wiring, and the drain regions 106 may be electrically connected by the drain wiring. The source wiring may include source contacts and a source connection line, and the drain wiring may have drain contacts and a drain connection line. The source and the drain contacts may make contact with the source and the drain regions 104 and 106, respectively. The source and the drain contacts may include polysilicon, metal and/or metal compound, and the source and the drain connection lines may also include polysilicon, metal and/or metal compound.

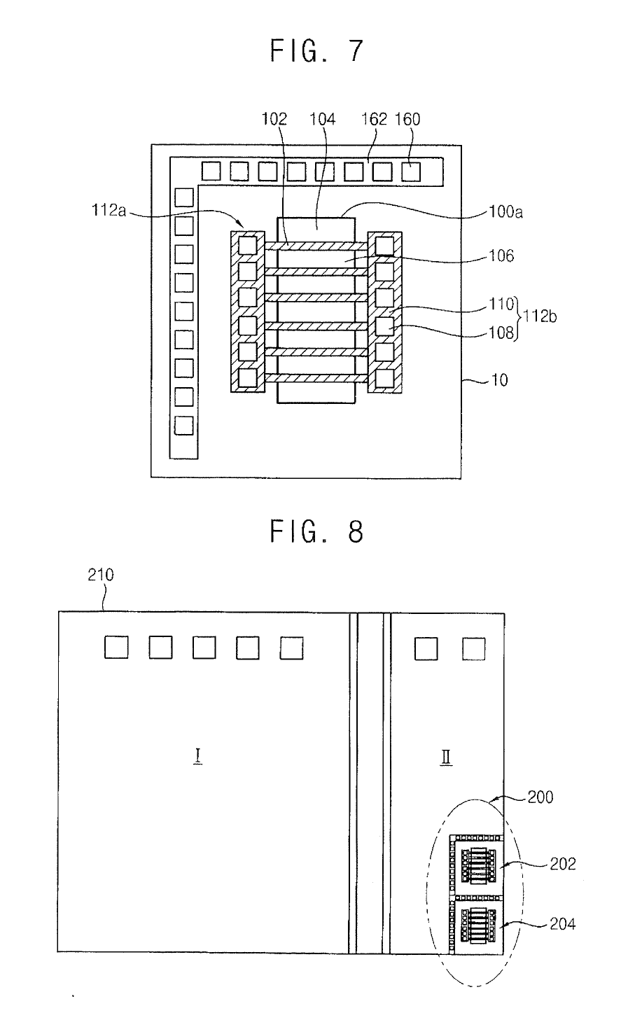

FIG. 7 is a plan view illustrating a multi-finger transistor in accordance with other example embodiments. In FIG. 7, the multi-finger transistor may have a construction substantially the same as or substantially similar to that of the multi-finger transistor described with reference to FIG. 1 except positions of substrate pads 160 and a conductive line 162.

Referring to FIG. 7, the multi-finger transistor includes gate fingers 102, source regions 104, drain regions 106, a first gate wiring 112a, a second gate wiring 112b, the substrate pads 160 and the conductive line 162.

The gate fingers 102 are disposed on a substrate 10 having an active region 100a and an isolation region. The gate fingers 102 include gate insulation layer patterns and gate electrodes, respectively. Source regions 104 and drain regions 106 are positioned at portions of the active region 100a between the gate fingers 102. The source and the drain regions 104 and 106 may be alternately disposed on the substrate 10.

The first and the second gate wiring 112a and 112b are formed on a first insulation interlayer (not illustrated) that covers the gate fingers 102. First and second end portions of the gate fingers 102 may be electrically connected each other by the first and the second gate wiring 112a and 112b, respectively. The first and the second gate wirings 112a and 112b include gate contacts 108 and gate lines 110. The gate contacts 108 may be electrically connected to the first and the second end portions of the gate fingers 102, and the gate contacts 108 may be electrically connected each other by the gate lines 110.

The conductive line 162 is positioned on a second insulation interlayer (not illustrated) that covers the first and the second gate wirings 112a and 112b. The conductive line 162 may be spaced apart from the gate fingers 102, the first gate wiring 112a and the second gate wiring 112b by a predetermined distance. The conductive line 162 may have an L-shaped structure that partially, but not fully, encloses a portion of the substrate 10 where the gate fingers 102, the first gate wiring 112a and the second gate wiring 112b are positioned. One conductive line 162 may be employed in one multi-finger transistor including the gate fingers 102. In example embodiments, the conductive line 162 may include a first portion and a second portion. The first portion of the conductive line 162 may be substantially parallel relative to the gate fingers 102, and the second portion of the conductive line 162 may be substantially parallel with respect to the first and the second gate wirings 112a and 112b.

The substrate plugs 160 contacting the substrate 10 are formed through the second and the first insulation interlayers. Since each of the substrate plugs 160 is grounded, the conductive line 162 connected to the substrate plugs 160 may be grounded, so that a generation of a noise caused through the substrate 10 may be prevented.

The multi-finger transistor further includes a source wiring (not illustrated) and a drain wiring (not illustrated) positioned on a third insulation interlayer (not illustrated) that covers the conductive line 162. The source and the drain regions 104 and 106 may be electrically connected by the source and the drain wirings, respectively. The source and the drain wirings include source and the drain contacts and source and the drain lines.

FIG. 8 is a plan view illustrating a semiconductor device including a multi-finger transistor in accordance with example embodiments. In FIG. 8, “I” represents a digital circuit area of a substrate 210 and “II” indicates an analog circuit area of the semiconductor device. The substrate 210 may be a bulk and/or multilayer integrated circuit substrate.

Referring to FIG. 8, multi-finger transistors 200 are disposed in the analog circuit area II of the substrate 210. For example, the multi-finger transistors 200 may be positioned at a peripheral portion of the analog area II. In example embodiments, the multi-finger transistors 200 may be arranged at a corner of the analog circuit area II.

In example embodiments, two multi-finger transistors 200 may have constructions substantially the same as or substantially similar to that of the multi-finger transistor described with reference to FIG. 7. A first multi-finger transistor 202 may be positioned at the corner of the analog circuit area II and a second multi-finger transistor 204 may be continuously disposed at the peripheral portion of the analog circuit area II. Thus, the transistors 202 and 204 are disposed adjacent one another. Each of the first and the second multi-finger transistors 202 and 204 may include gate fingers, source/drain regions, gate wirings, a conductive line and substrate plugs. The conductive lines of the first and the second multi-finger transistors 202 and 204 may be connected to each other. Thus, the gate fingers, the source/drain regions and the gate wirings of the first and the second multi-finger transistors 202 and 204 may be spaced apart by the conductive lines. For example, the conductive lines may partially enclose the gate fingers, the source/drain regions and the gate wirings of the first and the second multi-finger transistors 202 and 204.

In some example embodiments, a plurality of multi-finger transistors may be disposed at the peripheral portion of the analog circuit area II adjacent one another. Here, the plurality of multi-finger transistors may be arranged such as the first and the second multi-finger transistors 202 and 204.

When the semiconductor device includes the multi-finger transistors 200 as illustrated in FIG. 8, cross talk between a peripheral portion of the substrate and the conductive lines may be considerably reduced. Therefore, the semiconductor device may have improved cut-off frequency and maximum oscillation characteristics while allowing reduced size of the semiconductor device.

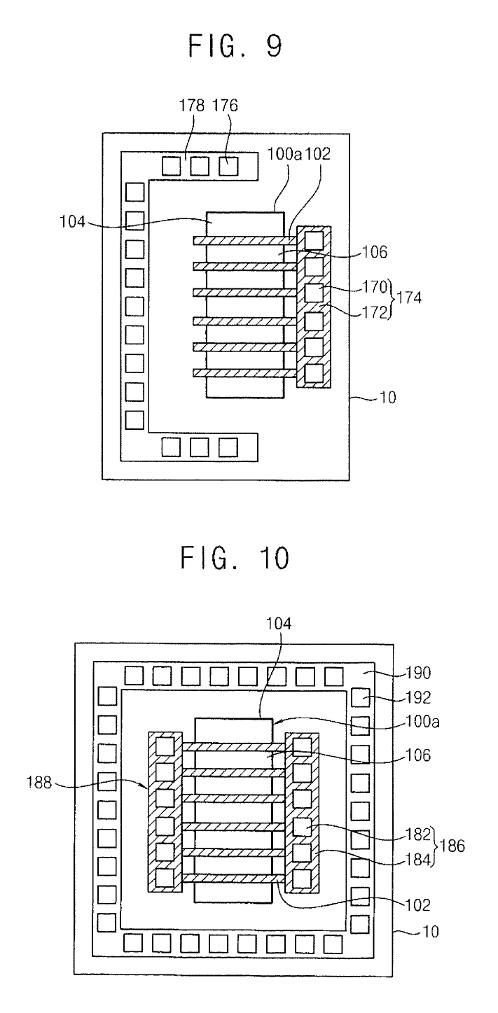

FIG. 9 is a plan view illustrating a multi-finger transistor in accordance with yet other example embodiments.

Referring to FIG. 9, the multi-finger transistor includes gate fingers 102 formed on a substrate 10, a gate wiring 174, source and drain regions 104 and 106, substrate plugs 176 and a conductive line 178.

The substrate 10 is divided into an active region 110a and an isolation region when an isolation layer (not illustrated) is formed on the substrate. Each of the gate fingers 102 may across the active region 100a of the substrate 10. The gate fingers 102 may be arranged on the substrate 10 substantially in parallel each other. In example embodiments, the gate fingers 102 may include gate insulation layer patterns and gate electrodes, respectively.

The source regions 104 and the drain regions 106 may be alternately arranged among the gate fingers 102. The source and the drain regions 104 and 106 may be formed at portions of the active region 100a between the gate fingers 102.

The gate wiring 174 is provided on a first insulation interlayer (not illustrated) formed on the substrate 10. The gate wiring 174 includes a plurality of gate contacts 170 and a gate line 172. The gate contacts 170 may make contact with end portions of the gate fingers 102. The gate line 172 is connected to the gate contacts 170.

In example embodiments, only one of end portions of each gate finger 102 may be electrically connected to the gate wiring 174. When the gate wiring 174 is electrically connected to one end portion of each gate finger 102, the multi-finger transistor may be referred to as a comb type multi-finger transistor. The multi-finger having the comb type may have a gate resistance substantially larger than those of the multi-finger transistors having the folded types described with reference to FIGS. 1, 6 and 7. However, the multi-finger transistor having the comb type may have a parasitic capacitance substantially smaller than those of the multi-finger transistors having the folded types.

The conductive line 178 is disposed on a second insulation interlayer (not illustrated) formed on the gate wiring 174. The conductive line 178 includes a first portion and second portions. The first portion of the conductive line 178 may be substantially parallel relative to the gate wiring 174 and the second portions of the conductive line 178 may be substantially parallel relative to the gate fingers 102. The first and the second portions of the conductive line 178 may partially, but not fully, enclose the gate fingers 102 and the gate wirings 174. Further, the first and the second portions of the conductive line 178 may be spaced apart from the gate fingers 102 and the gate wiring 174 by a predetermined interval.

The substrate plugs 176 are formed through the second and the first insulation interlayers to contact predetermined portions of the substrate 10. The conductive line 178 may be electrically connected to the substrate 10 through the substrate plugs 176. In example embodiments, a plurality of substrate plugs 178 may be arranged at a peripheral portion of the substrate by a substantially equal interval. Some substrate plugs 176 connected to the second portions of the conductive line 178 may be arranged substantially parallel to the gate fingers 102. Other substrate plugs 176 connected to the first portion of the conductive line 178 may be arranged substantially parallel to the gate wiring 174.

When the multi-finger transistor includes the conductive line 178 relatively separated from the gate wiring 174 illustrated in FIG. 9, the multi-finger transistor may have greatly reduced parasite capacitance.

A third insulation interlayer (not illustrated) is provided on the second insulation interlayer to cover the conductive line 178, a source wiring (not illustrated) and a drain wiring (not illustrated) are disposed on the third insulation interlayer. The source wiring includes source contacts and a source connection line, and the drain wiring also includes drain contacts and a drain connection line. The source and the drain contacts make contact with the source and the drain regions, respectively. The source and the drain contacts are connected to the source and the drain connection lines.

In some example embodiments, the multi-finger transistor may have various constructions based on a combination/subcombination of the constructions illustrated in FIGS. 1, 6, 7 and 9. For example, the multi-finger transistor may have a meander type that includes a plurality of gate wirings connected to two gate fingers.

FIG. 10 is a plan view illustrating a conventional multi-finger transistor according to comparative embodiments.

Referring to FIG. 10, the multi-finger transistor includes a conductive line 190 fully enclosing a portion of a substrate 10 where gate fingers 102, a first gate wiring 186 and a second gate wiring 188 are disposed. Substrate plugs 192 also fully enclose the gate fingers 102, the first gate wiring 186 and the second gate wiring 188.

Each of the first and the second gate wirings 186 and 188 includes gate contacts 182 and gate lines 184, which are electrically connected to the gate fingers 102 disposed on an active region 100a of the substrate 10. Further, source regions 104 and the drain regions 1066 are disposed at portions of the active region 100a between the gate fingers 102.

Table 1 shows several electrical characteristics of multi-finger transistors according to example and comparative embodiments.

TABLE 1

| | | Fmax | | |
|---|---|---|---|---|
| | FT [GHz] | [GHz] | Idst [μA/μm] | Cgg [fF] |
| Multi-finger | 138 | 272 | 628 | 21.2 |
| transistor in FIG. 6 | | | | |
| Multi-finger | 147 | 189 | 623 | 19.9 |
| transistor in FIG. 9 | | | | |
| Multi-finger | 136 | 193 | 628 | 21.7 |
| transistor in FIG. 10 | | | | |

As shown in Table 1, the multi-finger transistors having the conductive lines partially, but not fully, enclosing the gate fingers and the gate wiring(s) may have relatively high cut-off frequency and maximum oscillation characteristics in comparison with those of the multi-finger transistor having a conductive line fully enclosing the gate fingers and the gate wirings. Therefore, the multi-finger transistors having the conductive lines partially enclosing the gate fingers and the gate wiring(s) may provide high RF characteristics. Further, the multi-finger transistors having the conductive lines partially enclosing the gate fingers and the gate wiring(s) may have drain saturation current and capacitances between adjacent gates, so that the multi-finger transistors having the conductive lines partially enclosing the gate fingers and the gate wiring(s) may have improved driving operation substantially the same as or substantially similar to those of the multi-finger transistor having the conductive line fully enclosing the gate fingers and the gate wirings.

The foregoing is illustrative of example embodiments, and is not to be construed as limiting thereof. Although a few example embodiments have been described, those skilled in the art will readily appreciate that many modifications are possible in the example embodiments without materially departing from the novel teachings and advantages of example embodiments. Accordingly, all such modifications are intended to be included within the scope of example embodiments as defined in the claims. In the claims, means-plus-function clauses are intended to cover the structures described herein as performing the recited function and not only structural equivalents but also equivalent structures. Therefore, it is to be understood that the foregoing is illustrative of example embodiments and is not to be construed as limited to the specific embodiments disclosed, and that modifications to the disclosed example embodiments, as well as other example embodiments, are intended to be included within the scope of the appended claims. The invention is defined by the following claims, with equivalents of the claims to be included therein.

1. A semiconductor device comprising:
a substrate;
gate fingers disposed on the substrate;
at least one gate wiring connected to end portions of the gate fingers;
source regions and drain regions in the substrate, disposed between the gate fingers;
a conductive line partially enclosing the gate fingers and the gate wiring, the conductive line being separated from the gate fingers and the gate wiring; and
at least one substrate plug electrically connecting the conductive line to the substrate.

2. The semiconductor device of claim 1, wherein the at least one gate wiring comprises:
a first gate wiring connected to first end portions of the gate fingers; and
a second gate wiring connected to second end portions of the gate fingers.

3. The semiconductor device of claim 1, wherein the at least one gate wiring comprises:
gate contacts contacting the end portions of the gate fingers; and
a gate line connected to the gate contacts.

4. The semiconductor device of claim 1, wherein the conductive line includes a first portion substantially parallel to the gate fingers and second portions substantially parallel to the gate wiring.

5. The semiconductor device of claim 1, wherein the conductive line includes a first portion substantially parallel to the gate wiring and second portions substantially parallel to the gate fingers.

6. The semiconductor device of claim 1, wherein the conductive line includes a first portion substantially parallel to one of the gate wiring or the gate fingers and a second portion substantially parallel to another of the gate fingers or the gate wiring.

7. The semiconductor device of claim 1, wherein the source regions and the drain regions are alternately disposed between the gate fingers.

8. The semiconductor device of claim 1, further comprising:
a source wiring electrically connecting the source regions; and
a drain wiring electrically connecting the drain regions.

9. The semiconductor device of claim 8, wherein the source wiring comprises source contacts electrically contacting the source regions and a source connection line connected to the source contacts, and wherein the drain wiring comprises drain contacts electrically contacting the drain regions and a drain connection line connected to the drain contacts.

10. The semiconductor device of claim 1, wherein the conductive line is a U-shaped or an L-shaped conductive line.

11. A semiconductor device comprising:
a substrate including an active region;
a plurality of gate fingers disposed to cross the active region of the substrate;
a plurality of gate contacts connected to end portions of the gate fingers;
at least one gate line electrically connected to the gate contacts;
a plurality of source regions and drain regions in the substrate, alternately disposed between the gate fingers;
a conductive line partially enclosing the gate fingers and the gate line, the conductive line being separated from the gate fingers and the gate line; and
a plurality of substrate plugs that electrically connect the conductive line to the substrate.

12. The semiconductor device of claim 11, further comprising:
a source wiring including source contacts connected to the source regions and a source connection line connected to the source contacts; and
a drain wiring including drain contacts connected to the drain regions and a drain connection line connected to the drain contacts.

13. The semiconductor device of claim 12, further comprising a first insulation interlayer disposed between the gate fingers and the at least one gate line, wherein the gate contacts extend through the first insulation interlayer.

14. The semiconductor device of claim 13, further comprising a second insulation layer disposed between the at least one gate line and the conductive line, wherein the substrate plugs extend through the first and the second insulation interlayers.

15. The semiconductor device of claim 14, further comprising a third insulation interlayer disposed between the conductive line and the source and the drain wirings, wherein the source and the drain contacts extend through the first, the second and the third insulation interlayers.

16. The semiconductor device of claim 11, wherein the conductive line includes a first portion extending substantially parallel to one of the gate fingers or the at least one gate line, and a second portion extending substantially parallel to another of the at least one gate line or the gate fingers.

17. The semiconductor device of claim 11, wherein the conductive line is a U-shaped or an L-shaped conductive line.

18. A semiconductor device comprising:
a substrate having a digital circuit area and an analog circuit area; and
multi-finger transistors arranged in the analog circuit area, the multi-finger transistors being disposed adjacent one another at a peripheral portion of the analog circuit area.

19. The semiconductor device of claim 18, wherein each of the multi-finger transistors comprises:
gate fingers disposed on the analog circuit area;
at least one gate wiring connected to end portions of the gate fingers;
source regions and drain regions disposed between the gate fingers;
a conductive line partially enclosing the gate fingers and the gate wiring, the conductive line being separated from the gate fingers and the gate wiring; and
substrate plugs electrically connecting the conductive line to the substrate.

20. The semiconductor device of claim 18, wherein the conductive line is a U-shaped or an L-shaped conductive line.

21.-23. (canceled)
